(19) United States
(12) Patent Application Publication
(10) Pub. No.: US 2026/0094626 A1
(43) Pub. Date: Apr. 2, 2026

(54) THREE-DIMENSIONAL MEMORY DEVICE WITH BIT LINE TRANSISTOR

(71) Applicant: Taiwan Semiconductor Manufacturing Company, Ltd., Hsinchu (TW)

(72) Inventors: Chen-Jun Wu, Hsinchu City (TW); Chieh Lee, Hsinchu (TW); Yi-Ching Liu, Hsinchu City (TW); Kota Shiba, Hsinchu (TW); Shinichiro Shiratake, Hsinchu (TW); Katherine H. Chiang, New Taipei City (TW)

(21) Appl. No.: 19/043,791

(22) Filed: Feb. 3, 2025

Related U.S. Application Data
(60) Provisional application No. 63/701,026, filed on Sep. 30, 2024.

(51) Int. Cl. G11C 5/06; G11C 11/408; G11C 11/4091; G11C 11/4094; G11C 11/4096

(52) U.S. Cl. CPC G11C 5/063; G11C 11/4085; G11C 11/4091; G11C 11/4094; G11C 11/4096

(57) ABSTRACT

A circuit includes a first bit line, a second bit line, a first word line, a second word line, a first memory cell, a second memory cell, a first sense amplifier, a first bit line transistor, and a second bit line transistor. The first memory cell is coupled to the first bit line and the first word line. The second memory cell is coupled to the second bit line and the second word line. The first sense amplifier has a first terminal. The first bit line transistor selectively couples the first bit line to the first terminal of the first sense amplifier. The second bit line transistor selectively couples the second bit line to the first terminal of the first sense amplifier.

### REFERENCE TO RELATED APPLICATION

This Application claims the benefit of U.S. Provisional Application No. 63/701,026, filed on Sep. 30, 2024, the contents of which are hereby incorporated by reference in their entirety.

### BACKGROUND

Two-dimensional (2D) memory arrays are prevalent in electronic devices and may include, for example, NOR flash memory arrays, NAND flash memory arrays, dynamic random access memory (DRAM) arrays, and so on. However, 2D memory arrays are reaching scaling limits and are hence reaching limits on memory density. Three-dimensional (3D) memory arrays are a promising candidate for increasing memory density and may include, for example, 3D DRAM flash memory arrays, 3D NOR flash memory arrays, 3D NAND flash memory arrays, and so on.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of some embodiments of a three-dimensional dynamic random access memory (DRAM) device including a bit line transistor selectively coupling a bit line to a sense amplifier.

FIG. 2 illustrates a timing diagram of some embodiments of a read and/or write operation for reading and/or writing a first memory cell of the three-dimensional DRAM device of FIG. 1.

FIG. 3 illustrates a flow diagram of some embodiments of a method for reading and/or writing a memory cell of the three-dimensional DRAM device of FIG. 1

FIG. 4 illustrates a cross-sectional view of some embodiments of an integrated chip including the three-dimensional DRAM device of FIG. 1.

FIG. 5 illustrates a circuit diagram of some embodiments of the three-dimensional DRAM device of FIG. 1 further including complementary bit lines.

FIG. 6 illustrates a circuit diagram of some embodiments of the three-dimensional DRAM device of FIG. 1 further including a second sense amplifier.

FIG. 7 illustrates a three-dimensional view of some embodiments of three-dimensional DRAM device of FIG. 6.

FIGS. 8-12 illustrate cross-sectional views of various embodiments of the integrated chip of FIG. 4.

FIG. 13 illustrates a circuit diagram of some embodiments of the sense amplifier.

FIGS. 14-20 illustrate cross-sectional views of some embodiments of a method for forming an integrated chip including a three-dimensional DRAM device with a bit line transistor selectively coupling a bit line to a sense amplifier.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A dynamic random access memory (DRAM) device includes a sense amplifier, a first bit line, a second bit line, a first word line, and a second word line. The DRAM device includes a first memory cell coupled to the first bit line and the first word line. The DRAM device includes a second memory cell coupled to the second bit line and the second word line. The second bit line is spaced over the first bit line, the second word line is spaced over the first word line, and the second memory cell is spaced over the first memory cell in a three-dimensional arrangement to increase the memory density of the DRAM device.

In some devices, the first bit line and the second bit line are coupled to a first terminal of the sense amplifier in a “shared” bit line arrangement to reduce the number of sense amplifiers in the DRAM device. However, this shared bit line arrangement may make it harder to accurately read the memory cells of the three-dimensional DRAM device. For example, the first bit line has a first parasitic capacitance, and the second bit line has a second parasitic capacitance. In the shared bit line arrangement, both the parasitic capacitance of the first bit line and the parasitic capacitance of the second bit line are coupled to the first terminal of the sense amplifier, and thus a total capacitance at the first terminal of the sense amplifier may be increased. Consequently, the amplitudes of signals sensed by the first sense amplifier when reading the memory cells may be reduced (e.g., the read margin may be reduced), and thus it may be more difficult to accurately read the memory cells. Further, as the number of bit lines coupled to the first terminal of the sense amplifier increases, the total capacitance at the first terminal of the sense amplifier increases, and thus the difficulty of accurately reading the memory cells increases.

In various embodiments of the present disclosure, the three-dimensional DRAM device includes a first bit line transistor selectively coupling the first bit line to the first terminal of the sense amplifier and a second bit line transistor selectively coupling the second bit line to the first terminal of the sense amplifier to improve the readability of memory cells on the first and second bit lines. For example, when reading and/or writing the first memory cell, the first bit line transistor couples the first bit line to the first terminal of the sense amplifier and the second bit line transistor isolates the second bit line from the first terminal of the first sense amplifier. Thus, when reading and/or writing the first memory cell, the second bit line transistor can isolate the parasitic capacitance on the second bit line from the first terminal of the sense amplifier, and thus a total capacitance at the first terminal of the sense amplifier can be reduced. By reducing the total capacitance at the first terminal of the sense amplifier, the amplitude of the signal sensed by the first sense amplifier when reading the first memory cell can be improved (e.g., the read margin may be improved), and thus it may be easier to accurately read the first memory cell.

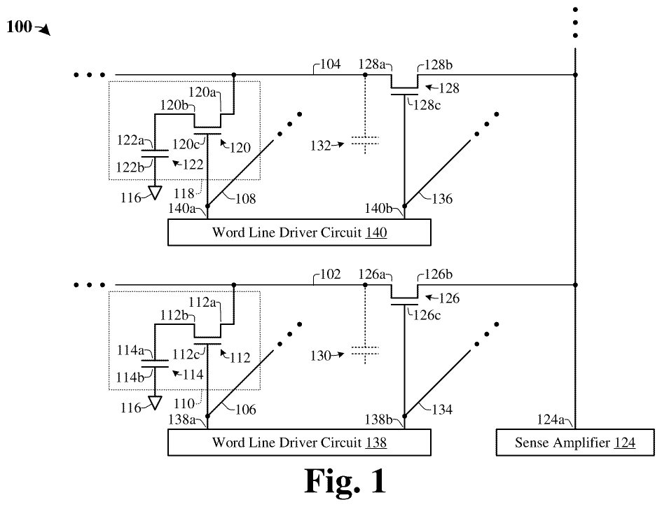

FIG. 1 illustrates a circuit diagram 100 of some embodiments of a three-dimensional dynamic random access memory (DRAM) device including a bit line transistor selectively coupling a bit line to a sense amplifier.

The DRAM device includes a first bit line 102, a second bit line 104, a first word line 106, and a second word line 108. The DRAM device includes a first memory cell 110 and a second memory cell 118. The first memory cell 110 is coupled to the first bit line 102 and the first word line 106. The first memory cell 110 includes a first memory cell transistor 112 and a first memory cell capacitor 114. The first memory cell transistor 112 selectively couples the first memory cell capacitor 114 to the first bit line 102. The second memory cell 118 is coupled to the second bit line 104 and the second word line 108. The second memory cell 118 includes a second memory cell transistor 120 and a second memory cell capacitor 122. The second memory cell transistor 120 selectively couples the second memory cell capacitor 122 to the second bit line 104.

The DRAM device includes a first sense amplifier 124 having a first terminal 124a. The DRAM device further includes a first bit line transistor 126 and a second bit line transistor 128. The first bit line transistor 126 selectively couples the first bit line 102 to the first terminal 124a of the first sense amplifier 124. The second bit line transistor 128 selectively couples the second bit line 104 to the first terminal 124a of the first sense amplifier 124.

For example, when reading and/or writing the first memory cell 110, the first bit line transistor 126 couples the first bit line 102 to the first terminal 124a of the first sense amplifier 124, and the second bit line transistor 128 isolates the second bit line from the first terminal 124a of the first sense amplifier 124. Thus, when reading and/or writing the first memory cell, the second bit line transistor 128 can isolate a parasitic capacitance 132 on the second bit line 104 from the first terminal 124a of the first sense amplifier 124 and thus a total capacitance at the first terminal 124a of the first sense amplifier 124 can be reduced. By reducing the total capacitance at the first terminal 124a of the first sense amplifier 124, the signal sensed by the first sense amplifier 124 when reading the first memory cell 110 can be improved (e.g., the read margin can be improved). As a result, the likelihood of accurately reading the first memory cell 110 can be improved. Further, although the bit line transistors have capacitance, this capacitance is substantially less than the parasitic capacitances that are isolated from the first terminal 124a of the first sense amplifier 124 by the bit line transistors when reading and/or writing.

Similarly, when reading and/or writing the second memory cell 118, the second bit line transistor 128 couples the second bit line to the first terminal 124a of the first sense amplifier 124, and the first bit line transistor 126 isolates the first bit line 102 from the first terminal 124a of the first sense amplifier 124 to isolate a parasitic capacitance 130 on the first bit line 102 from the first terminal 124a of the first sense amplifier 124 to reduce the total capacitance at the first terminal 124a of the first sense amplifier 124.

The first bit line transistor 126 has a first terminal 126a, a second terminal 126b, and a control terminal 126c. The first terminal 126a is coupled to the first bit line 102. The second terminal 126b is coupled to the first terminal 124a of the first sense amplifier 124. The control terminal 126c is coupled to a first switch line 134.

The second bit line transistor 128 has a first terminal 128a, a second terminal 128b, and a control terminal 128c. The first terminal 128a is coupled to the second bit line 104. The second terminal 128b is coupled to the first terminal 124a of the first sense amplifier 124. The control terminal 128c is coupled to a second switch line 136.

The DRAM device includes a first word line driver circuit 138 having a first output terminal 138a coupled to the first word line 106 and a second output terminal 138b coupled to the first switch line 134. The first word line driver circuit 138 drives (e.g., provides voltage to) the first word line 106 and the first switch line 134. The DRAM device includes a second word line driver circuit 140 having a first output terminal 140a coupled to the second word line 108 and a second output terminal 140b coupled to the second switch line 136. The second word line driver circuit 140 drives the second word line 108 and the second switch line 136.

The first memory cell transistor 112 has a first terminal 112a, a second terminal 112b, and a control terminal 112c. The first memory cell capacitor 114 has a first terminal 114a and a second terminal 114b. The first terminal 112a of the first memory cell transistor 112 is coupled to the first bit line 102. The second terminal 112b of the first memory cell transistor 112 is coupled to the first terminal 114a of the first memory cell capacitor 114. The control terminal 112c of the first memory cell transistor 112 is coupled to the first word line 106. The second terminal 114b of the first memory cell capacitor 114 is coupled to a reference voltage terminal 116 (e.g., ground).

The second memory cell transistor 120 has a first terminal 120a, a second terminal 120b, and a control terminal 120c. The second memory cell capacitor 122 has a first terminal 122a and a second terminal 122b. The first terminal 120a of the second memory cell transistor 120 is coupled to the second bit line 104. The second terminal 120b of the second memory cell transistor 120 is coupled to the first terminal 122a of the second memory cell capacitor 122. The control terminal 120c of the second memory cell transistor 120 is coupled to the second word line 108. The second terminal 122b of the second memory cell capacitor 122 is coupled to the reference voltage terminal 116 (e.g., ground).

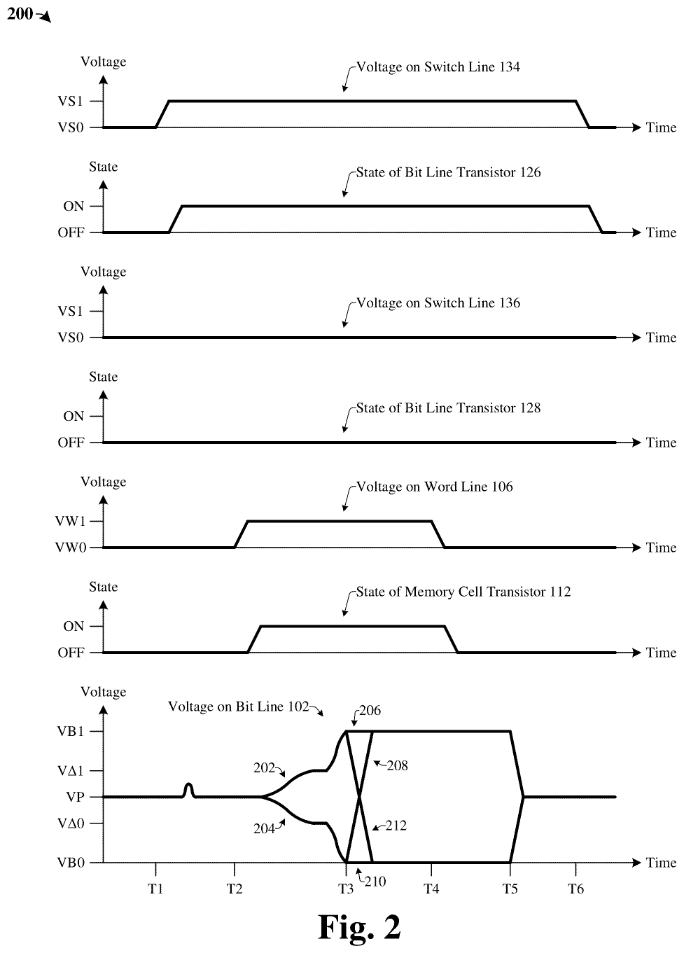

FIG. 2 illustrates a timing diagram 200 of some embodiments of a read and/or write operation for reading and/or writing the first memory cell 110 of the three-dimensional DRAM device of FIG. 1.

At a first time T1, the first word line driver circuit 138 provides a first switch line voltage VS1 (e.g., a “high” voltage) to the first switch line 134 via output terminal 138b to assert the first switch line 134. In response, the first bit line transistor 126 turns ON, thereby coupling the first bit line 102 to the first terminal 124a of the first sense amplifier 124. Further, at the first time T1, the second word line driver circuit 140 provides a second switch line voltage VS0 (e.g., a “low” voltage) to the second switch line 136 via output terminal 140b. In response, the second bit line transistor 128 turns OFF (or remains OFF), thereby isolating the second bit line 104 from the first terminal 124a of the first sense amplifier 124. In response to the first bit line transistor 126 coupling the first bit line 102 to the first terminal 124a of the first sense amplifier 124 (and the second bit line transistor 128 isolating the second bit line 104 from the first terminal 124a of the first sense amplifier 124), the first sense amplifier 124 provides a pre-charge voltage VP (e.g., a standby voltage) to the first bit line 102 via terminal 124a.

At a second time T2, in response to the first bit line 102 being pre-charged to the pre-charge voltage VP, the first word line driver circuit 138 provides a first word line voltage VW1 (e.g., a “high” voltage) to the first word line 106 via output terminal 138a to assert the first word line 106. In response, the first memory cell transistor 112 turns ON, thereby coupling the first bit line 102 to the first memory cell capacitor 114. In response, the first memory cell capacitor 114 either discharges to the first bit line 102 or charges from the first bit line 102, depending on the charge of the first memory cell capacitor 114 (which indicates the value stored in the first memory cell capacitor 114). In response, the first sense amplifier 124 senses (e.g., determines) the change in the voltage from the pre-charge voltage VP on the first bit line 102 and determines the value stored in the first memory cell 110 (e.g., reads the first memory cell 110) based on the voltage change on the first bit line 102.

For example, when the first memory cell capacitor 114 is charged (e.g., a voltage at the first terminal 114a is greater than the pre-charge voltage VP) indicating that a first value (e.g., logic 1) is stored in the first memory cell 110, the voltage on the first bit line 102 increases (e.g., from the pre-charge voltage VP to a first change voltage VΔ1) in response to the first memory cell transistor 112 coupling the first bit line 102 to the first memory cell capacitor 114, as illustrated at 202. The sense amplifier 124 senses the increase in the voltage on the first bit line 102 and determines that the value stored in the first memory cell 110 is the first value (e.g., logic 1).

Conversely, the when the first memory cell capacitor 114 is discharged (e.g., a voltage at terminal 114a is less than the pre-charge voltage, such as ground) indicating a second value (e.g., a logic 0) is stored in the first memory cell 110, the voltage on the first bit line 102 decreases (e.g., from the pre-charge voltage VP to a second change voltage VΔ2) in response to the first memory cell transistor 112 coupling the first bit line 102 to the first memory cell capacitor 114, as illustrated at 204. The sense amplifier 124 senses the decrease in the voltage on the first bit line 102 and determines that the value stored in the first memory cell 110 is the second value (e.g., logic 0).

At a third time T3, in response to the first sense amplifier 124 determining the value stored in the first memory cell 110, the first sense amplifier 124 provides a write voltage to the first bit line 102 (via terminal 124a) to write the first memory cell 110. For example, to write a first value (e.g., logic 1) to the first memory cell 110, the first sense amplifier 124 provides a first write voltage VB1 (e.g., a voltage that is greater than the pre-charge voltage VP) to the first bit line 102 (via terminal 124a), as illustrated at 206 and 208. In response, the first memory cell capacitor 114 is charged to the first write voltage VB1. Conversely, to write a second value (e.g., logic 0) to the first memory cell 110, the first sense amplifier 124 provides a second write voltage VB0 (e.g., a voltage that is less than the pre-charge voltage VP) to the first bit line 102 (via terminal 124a), as illustrated at 210 and 212. In response, the first memory cell capacitor 114 is discharged.

At a fourth time T4, in response to writing the first memory cell 110, the first word line driver circuit 138 provides a second word line voltage VW0 (e.g., a “low” voltage) to the first word line 106 via output terminal 138a to de-assert the first word line 106.

At a fifth time T5, in response to the first word line 106 being de-asserted, the first sense amplifier 124 provides the pre-charge voltage VP (e.g., the standby voltage) to the first bit line 102 via terminal 124a.

At a sixth time T6, in response to the first sense amplifier 124 returning the bit line 102 to the pre-charge voltage VP, the first word line driver circuit 138 provides the second switch line voltage VS0 (e.g., the “low” voltage) to the first switch line 134 via output terminal 138b. In response, the first bit line transistor 126 turns OFF, thereby isolating the first bit line 102 from the first terminal 124a of the first sense amplifier 124.

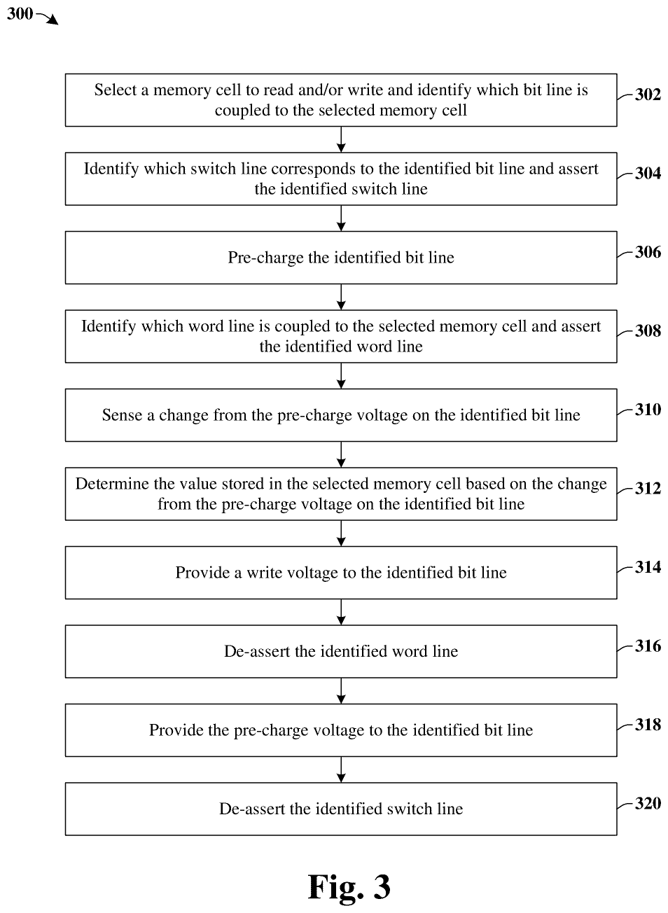

FIG. 3 illustrates a flow diagram 300 of some embodiments of a method for reading and/or writing a memory cell of the three-dimensional DRAM device of FIG. 1. While flow diagram 300 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 302, select a memory cell to read and/or write and identify which bit line is coupled to the selected memory cell. For example, the first memory cell 110 is selected and thus the first bit line 102 is identified.

At block 304, identify which switch line corresponds to the identified bit line and assert the identified switch line. For example, the first switch line 134 is identified and the first word line driver circuit 138 asserts the first switch line 134. In response, the first bit line transistor 126 turns ON, thereby coupling the first bit line 102 to the first terminal 124a of the first sense amplifier 124.

At block 306, pre-charge the identified bit line. For example, the first sense amplifier 124 provides a pre-charge voltage to the first bit line 102 through the first bit line transistor 126.

At block 308, identify which word line is coupled to the selected memory cell and assert the identified word line. For example, the first word line 106 is identified and the first word line driver circuit 138 asserts the first word line 106. In response, the first memory cell transistor 112 turns ON, thereby coupling the first bit line 102 to the first memory cell capacitor 114.

At block 310, sense a change from the pre-charge voltage on the identified bit line. For example, the first sense amplifier 124 senses a change from the pre-charge voltage on the first bit line 102.

At block 312, determine the value stored in the selected memory cell based on the change from the pre-charge voltage on the identified bit line. For example, the first sense amplifier 124 determines the value stored in the first memory cell 110 based on the change from the pre-charge voltage on the first bit line 102.

At block 314, provide a write voltage to the identified bit line. For example, the first sense amplifier 124 provides a write voltage to the first bit line 102 through the first bit line transistor 126 to charge or discharge the first memory cell capacitor 114 to write the first memory cell 110.

At block 316, de-assert the identified word line. For example, the first word line driver circuit 138 de-asserts the first word line 106.

At block 318, provide the pre-charge voltage to the identified bit line. For example, the first sense amplifier 124 provides the pre-charge voltage to the first bit line 102 through the first bit line transistor 126.

At block 320, de-assert the identified switch line. For example, the first word line driver circuit 138 de-asserts the first switch line 134. In response, the first bit line transistor 126 turns OFF, thereby decoupling (e.g., isolating) the first bit line 102 from the first terminal 124a of the first sense amplifier 124.

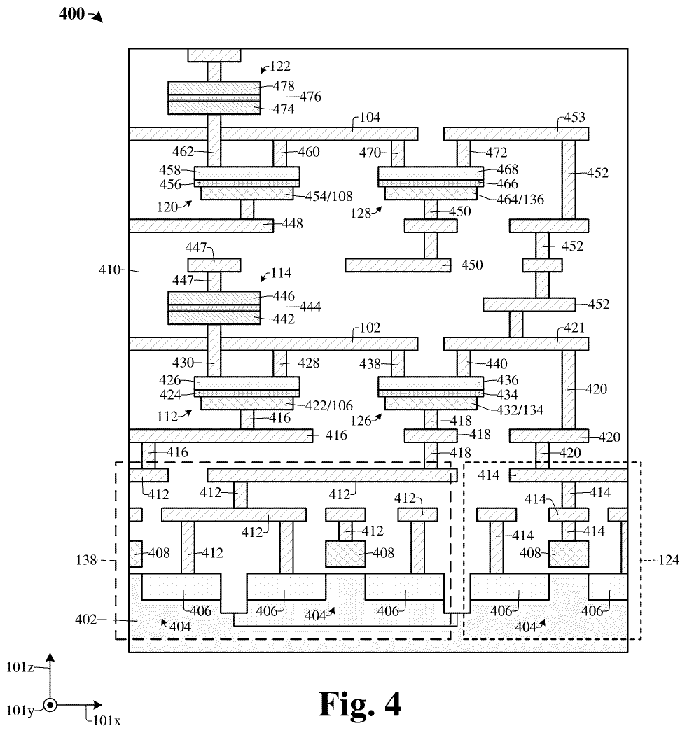

FIG. 4 illustrates a cross-sectional view 400 of some embodiments of an integrated chip including the three-dimensional DRAM device of FIG. 1.

The integrated chip includes a semiconductor substrate 402. The word line driver circuits 138, 140 and the first sense amplifier 124 are arranged along the semiconductor substrate 402. For example, in some embodiments, the word line driver circuits 138, 140 and the first sense amplifier 124 include transistors 404 along the semiconductor substrate 402. The transistors 404 includes source/drains 406 and gates 408. In some embodiments, the word line driver circuits 138, 140 and the first sense amplifier 124 further include conductive interconnects 412 and conductive interconnects 414, respectively, that are within a dielectric structure 410 that is over the semiconductor substrate 402. In some embodiments, one or more of the conductive interconnects 414 form the first terminal 124a of the first sense amplifier 124. In some embodiments, conductive interconnects form the output terminals of the word line driver circuits.

The first memory cell 110, the second memory cell 118, the first bit line 102, the second bit line 104, the first word line 106, and the second word line 108 are within the dielectric structure 410 and spaced over the word line driver circuits 138, 140 and the sense amplifier(s) 124 that are disposed along the semiconductor substrate 402. For example, the first memory cell capacitor 114 includes: a first electrode layer 442 (corresponding to terminal 114a); a second electrode layer 446 (corresponding to terminal 114b); and an insulator layer 444 between the first electrode layer 442 and the second electrode layer 444. Further, the first memory cell transistor 112 includes: a first source/drain electrode 428 (corresponding to terminal 112a); a second source/drain electrode 430 (corresponding to terminal 112b); a channel layer 426 extending from the first source/drain electrode 428 to the second source/drain electrode 430; a gate electrode 422 (corresponding to control terminal 112c) between the first source/drain electrode 428 and the second source/drain electrode 430; and a gate dielectric layer 424 between the channel layer 426 and the gate electrode 422. In some embodiments, the first word line 106 is or forms the gate electrode 422. The gate electrode 422 is coupled to the first word line driver circuit 138 by conductive interconnects 416. The first source/drain electrode 428 extends from the channel layer 426 to the first bit line 102. The second source/drain electrode 430 extends from the channel layer 426 to the first electrode layer 442 of the first memory cell capacitor 114. The second electrode layer 446 of the first memory cell capacitor 114 is coupled to reference voltage terminal 116 by conductive interconnects 447.

Similarly, the second memory cell capacitor 122 includes: a first electrode layer 474 (corresponding to terminal 122a); a second electrode layer 478 (corresponding to terminal 122b); and an insulator layer 476 between the first electrode layer 474 and the second electrode layer 478. Further, the second memory cell transistor 120 includes: a first source/drain electrode 460 (corresponding to terminal 120a); a second source/drain electrode 462 (corresponding to terminal 120b); a channel layer 458 extending from the first source/drain electrode 460 to the second source/drain electrode 462; a gate electrode 454 (corresponding to control terminal 120c) between the first source/drain electrode 460 and the second source/drain electrode 462; and a gate dielectric layer 456 between the channel layer 458 and the gate electrode 454. In some embodiments, the second word line 108 is or forms the gate electrode 454. The gate electrode 454 is coupled to the second word line driver circuit 140 by conductive interconnects 448. The first source/drain electrode 460 extends from the channel layer 458 to the second bit line 104. The second source/drain electrode 462 extends from the channel layer 458 to the first electrode layer 474 of the second memory cell capacitor 122.

The second memory cell 118 is vertically spaced over the first memory cell 110 (e.g., along axis 101z). The second bit line 104 is vertically spaced over the first bit line 102. The second word line 108 is vertically spaced over the first word line 106.

The first bit line transistor 126, the second bit line transistor 128, the first switch line 134, and the second switch line 136 are within the dielectric structure 410 and spaced over the word line driver circuits 138, 140 and the sense amplifier(s) 124 that are disposed along the semiconductor substrate 402. For example, the first bit line transistor 126 includes: a first source/drain electrode 438 (corresponding to terminal 126a); a second source/drain electrode 440 (corresponding to terminal 126b); a channel layer 436 extending from the first source/drain electrode 438 to the second source/drain electrode 440; a gate electrode 432 (corresponding to control terminal 126c) between the first source/drain electrode 438 and the second source/drain electrode 440; and a gate dielectric layer 434 between the channel layer 436 and the gate electrode 432. In some embodiments, the first switch line 134 is or forms the gate electrode 432. The gate electrode 432 is coupled to the first word line driver circuit 138 by conductive interconnects 418. The first source/drain electrode 438 extends from the channel layer 436 to the first bit line 102. The second source/drain electrode 440 extends from the channel layer 436 to a conductive line 421, and conductive line 421 is coupled to the first input terminal 124a of the first sense amplifier 124 by conductive interconnects 420.

Similarly, the second bit line transistor 128 includes: a first source/drain electrode 470 (corresponding to terminal 128a); a second source/drain electrode 472 (corresponding to terminal 128b); a channel layer 468 extending from the first source/drain electrode 470 to the second source/drain electrode 472; a gate electrode 464 (corresponding to control terminal 128c) between the first source/drain electrode 470 and the second source/drain electrode 472; and a gate dielectric layer 466 between the channel layer 468 and the gate electrode 464. In some embodiments, the second switch line 136 is or forms the gate electrode 464. The gate electrode 464 is coupled to the second word line driver circuit 140 by conductive interconnects 450. The first source/drain electrode 470 extends from the channel layer 468 to the second bit line 104. The second source/drain electrode 472 extends from the channel layer 468 to a conductive line 453, and the conductive line 453 is coupled to the first terminal of the first sense amplifier 124 by conductive interconnects 452, 421, 420.

The second switch line 136 is vertically spaced over the first switch line 134 (e.g., along axis 101z). The first bit line transistor 126 is laterally spaced from the first memory cell transistor 112 (e.g., along axis 101x). The second bit line transistor 128 is laterally spaced from the second memory cell transistor 120 (e.g., along axis 101x) and vertically spaced from the first bit line transistor 126.

In some embodiments, the semiconductor substrate 402 comprises silicon or some other suitable semiconductor material. In some embodiments, source/drains 406 are doped regions of semiconductor substrate 402. In some embodiments, source/drain(s) may refer to a source or a drain, individually or collectively dependent upon the context. In some embodiments, gates 408 comprise polysilicon, tungsten, titanium, tantalum, or some other suitable material. In some embodiments, dielectric layers of dielectric structure 410 comprise silicon oxide, silicon nitride, silicon carbide, hafnium oxide, aluminum oxide, or some other suitable material. In some embodiments, conductive interconnects (e.g., 412, 414, 416, 418, 420, 421, 447, 448, 450, 452, 453) comprise metal such as, for example, tungsten, aluminum, copper, or some other suitable material. In some embodiments, the word lines, the bit lines, and the switch lines comprise metal such as, for example, tungsten, aluminum, copper, or some other suitable material. In some embodiments, the gate dielectric layers comprise silicon oxide, hafnium oxide, or some other suitable dielectric material. In some embodiments, the channel layers comprise a semiconductor such as, for example, silicon or some other suitable semiconductor material. In some embodiments, the source/drain electrodes comprise a metal such as, for example, gold, tungsten, aluminum, copper, or some other suitable material. In some embodiments, the electrode layers of the memory cell capacitors comprise a metal such as, for example, gold, tungsten, aluminum, copper, or some other suitable material. In some embodiments, the insulator layers of the memory cell capacitors comprise a dielectric such as, for example, silicon oxide, hafnium oxide, or some other suitable dielectric material.

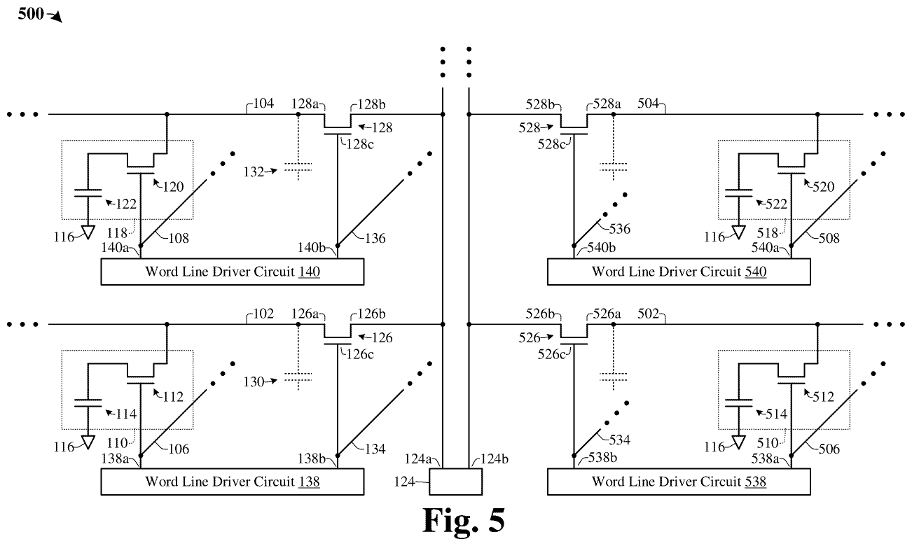

FIG. 5 illustrates a circuit diagram 500 of some embodiments of the three-dimensional DRAM device of FIG. 1 further including complementary bit lines selectively coupled to the first sense amplifier 124.

For example, the DRAM device includes a first complementary bit line 502 and a second complementary bit line 504. A memory cell 510 is coupled to the first complementary bit line 502 and a word line 506. Memory cell 510 includes a memory cell transistor 512 and a memory cell capacitor 514. Memory cell transistor 512 selectively couples memory cell capacitor 514 to the first complementary bit line 502. A memory cell 518 is coupled to the second complementary bit line 504 and a word line 508. Memory cell 518 includes a memory cell transistor 520 and a memory cell capacitor 522. Memory cell transistor 520 selectively couples memory cell capacitor 522 to the second complementary bit line 504.

The DRAM device further includes a first complementary bit line transistor 526 and a second complementary bit line transistor 528. The first complementary bit line transistor 526 selectively couples the first complementary bit line 502 to a second terminal 124b of the first sense amplifier 124. The second complementary bit line transistor 528 selectively couples the second complementary bit line 504 to the second terminal 124b of the first sense amplifier 124.

The first complementary bit line transistor 526 has a first terminal 526a, a second terminal 526b, and a control terminal 526c. The first terminal 526a is coupled the first complementary bit line 502. The second terminal 526b is coupled to the second terminal 124b of the first sense amplifier 124. The control terminal 526c is coupled to a switch line 534.

The second complementary bit line transistor 528 has a first terminal 528a, a second terminal 528b, and a control terminal 528c. The first terminal 528a is coupled the second complementary bit line 504. The second terminal 528b is coupled to the second terminal 124b of the first sense amplifier 124. The control terminal 528c is coupled to a switch line 536.

A word line driver circuit 538 has a first output terminal 538a coupled to word line 506 and a second output terminal 538b coupled to switch line 534. Word line driver circuit 538 drives word line 506 and switch line 534. A word line driver circuit 540 has a first output 540a coupled to word line 508 and a second output 540b coupled to switch line 536. Word line driver circuit 540 drives word line 508 and switch line 536.

When reading and/or writing the first memory cell 110, the first word line driver circuit 138 asserts the first switch line 134 and word line driver circuit 538 asserts switch line 534. In response, the first bit line transistor 126 couples the first bit line 102 to the first terminal 124a of the first sense amplifier 124 and the first complementary bit line transistor 526 couples the first complementary bit line 502 to the second terminal 124b of the first sense amplifier 124 (while the second bit line transistor 128 isolates the second bit line from the first terminal 124a of the first sense amplifier 124, and while the second complementary bit line transistor 528 isolates the second complementary bit line 504 from the second terminal 124b of the first sense amplifier 124). Next, the first sense amplifier 124 provides the pre-charge voltage to the first bit line 102 and the first complementary bit line 502. Next, the first word line driver circuit 138 asserts the first word line 106. In response, the first sense amplifier 124 senses (e.g., determines) a change from the pre-charge voltage on the first bit line 102 by comparing the voltage on the first bit line 102 to the pre-charge voltage on the first complementary bit line 502.

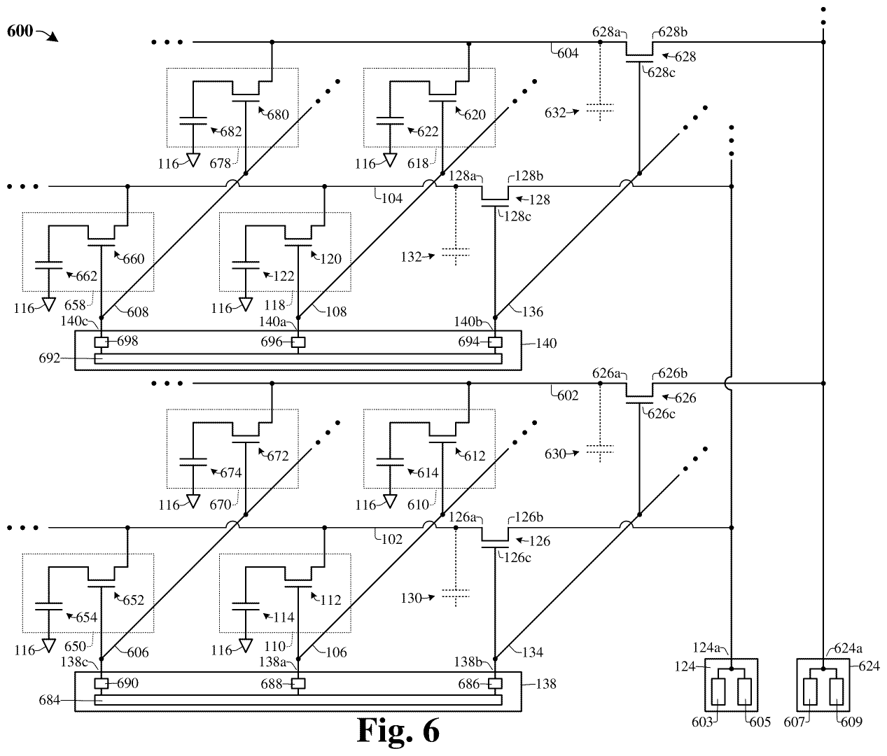

FIG. 6 illustrates a circuit diagram 600 of some embodiments of the three-dimensional DRAM device of FIG. 1 further including a second sense amplifier 624.

The DRAM device includes additional memory cells along the first word line 106 and the second word line 108. For example, a third memory cell 610 is coupled to the first word line 106 and a third bit line 602. The third memory cell 610 includes a third memory cell transistor 612 and a third memory cell capacitor 614. The third memory cell transistor 612 selectively couples the third memory cell capacitor 614 to the third bit line 602. Further, a fourth memory cell 618 is coupled to the second word line 108 and a fourth bit line 604. The fourth memory cell 618 includes a fourth memory cell transistor 620 and a fourth memory cell capacitor 622. The fourth memory cell transistor 620 selectively couples the fourth memory cell capacitor 622 to the fourth bit line 604.

The DRAM device includes additional memory cells along the first bit line 102 and the second bit line 104. For example, a fifth memory cell 650 is coupled to the first bit line 102 and a third word line 606. The fifth memory cell 650 includes a fifth memory cell transistor 652 and a fifth memory cell capacitor 654. The fifth memory cell transistor 652 selectively couples the fifth memory cell capacitor 654 to the first bit line 102. Further, a sixth memory cell 658 is coupled to the second bit line 104 and a fourth word line 608. The sixth memory cell 658 includes a sixth memory cell transistor 660 and a sixth memory cell capacitor 662. The sixth memory cell transistor 660 selectively couples the sixth memory cell capacitor 662 to the second bit line 104. The third word line 606 is coupled to an output terminal 138c of the first word line driver circuit 138. The fourth word line 608 is coupled to an output terminal 140c of the second word line driver circuit 140.

The DRAM device includes additional memory cells along the third bit line 602 and the fourth bit line 604. For example, a seventh memory cell 670 is coupled to the third bit line 602 and the third word line 606. The seventh memory cell 670 includes a seventh memory cell transistor 672 and a seventh memory cell capacitor 674. The seventh memory cell transistor 672 selectively couples the seventh memory cell capacitor 674 to the third bit line 602. Further, an eighth memory cell 678 is coupled to the fourth bit line 604 and the fourth word line 608. The eighth memory cell 678 includes an eighth memory cell transistor 680 and an eighth memory cell capacitor 682. The eighth memory cell transistor 680 selectively couples the eighth memory cell capacitor 682 to the fourth bit line 604.

The DRAM device includes additional sense amplifiers and bit line transistors according to the number of bit lines. For example, the DRAM device includes the second sense amplifier 624, a third bit line transistor 626 selectively coupling the third bit line 602 to a first terminal 624a of the second sense amplifier 624, and a fourth bit line transistor 628 selectively coupling the fourth bit line 604 to the first terminal 624a of the second sense amplifier 624.

The third bit line transistor 626 has a first terminal 626a, a second terminal 626b, and a control terminal 626c. The first terminal 626a is coupled the third bit line 602. The second terminal 626b is coupled to the first terminal 624a of the second sense amplifier 624. The control terminal 626c is coupled to the first switch line 134. Thus, the first word line driver circuit 138 drives the control terminal 126c of the first bit line transistor 126 and the control terminal 626c of the third bit line transistor 626 through output terminal 138b.

The fourth bit line transistor 628 has a first terminal 628a, a second terminal 628b, and a control terminal 628c. The first terminal 628a is coupled the fourth bit line 604. The second terminal 628b is coupled to the first terminal 624a of the second sense amplifier 624. The control terminal 628c is coupled to the second switch line 136. Thus, the second word line driver circuit 140 drives the control terminal 628c of the second bit line transistor 128 and the control terminal 628c of the fourth bit line transistor 628 through output terminal 140b.

When reading and/or writing the first memory cell 110, the first word line driver circuit 138 asserts the first switch line 134. In response, the first bit line transistor 126 and the third bit line transistor 626 turn ON, thereby coupling the first bit line 102 to the first terminal 124a of the first sense amplifier 124 and coupling the third bit line 602 to the first terminal 624a of the second sense amplifier 624. When reading and/or writing the first memory cell 110, the second switch line 136 in not asserted. Thus, the second bit line transistor 128 and the fourth bit line transistor 628 are OFF, thereby isolating the second bit line 104 (and parasitic capacitance 132) from the first terminal 124a of the first sense amplifier 124 and isolating the fourth bit line 604 (and parasitic capacitance 632) from the first terminal 624a of the second sense amplifier 624.

Similarly, when reading and/or writing the second memory cell 118, the second word line driver circuit 140 asserts the second switch line 136. In response, the second bit line transistor 128 and the fourth bit line transistor 628 turn ON, thereby coupling the second bit line 104 to the first terminal 124a of the first sense amplifier 124 and coupling the fourth bit line 604 to the first terminal 624a of the second sense amplifier 624. When reading and/or writing the second memory cell 118, the first switch line 134 in not asserted. Thus, the first bit line transistor 126 and the third bit line transistor 626 are OFF, thereby isolating the first bit line 102 (and parasitic capacitance 130) from the first terminal 124a of the first sense amplifier 124 and isolating the third bit line 602 (and parasitic capacitance 630) from the first terminal 624a of the second sense amplifier 624.

In some embodiments, the first word line driver circuit 138 includes a decoder 684 (e.g., logic circuitry) and drivers 686, 688, 690 coupled to the decoder 684. For example, an input (not labeled) of driver 686 is coupled to a first output (not labeled) of decoder 684, and an output of driver 686 is coupled to the first switch line 134. An input (not labeled) of driver 688 is coupled to a second output (not labeled) of decoder 684, and an output (not labeled) of driver 688 is coupled to the first word line 106. An input (not labeled) of driver 690 is coupled to a third output (not shown) of decoder 684, and an output (not labeled) of driver 690 is coupled to the third word line 606. Similarly, the second word line driver circuit 140 includes a decoder 692 and drivers 694, 696, 698. Drivers 694, 696, 698 are coupled to the decoder 692, the second switch line 136, the second word line 108, and the fourth word line 608 as shown.

In some embodiments, the first sense amplifier 124 includes a sensing circuit 603 and an equalization and pre-charge circuit 605. For example, a first terminal (not labeled) of the sensing circuit 603 and a first terminal (not labeled) of the equalization and pre-charge circuit 605 are coupled to the first terminal 124a of the first sense amplifier 124. Similarly, the second sense amplifier 624 includes a sensing circuit 607 and an equalization and pre-charge circuit 609 coupled to the first terminal 624a of the second sense amplifier 624.

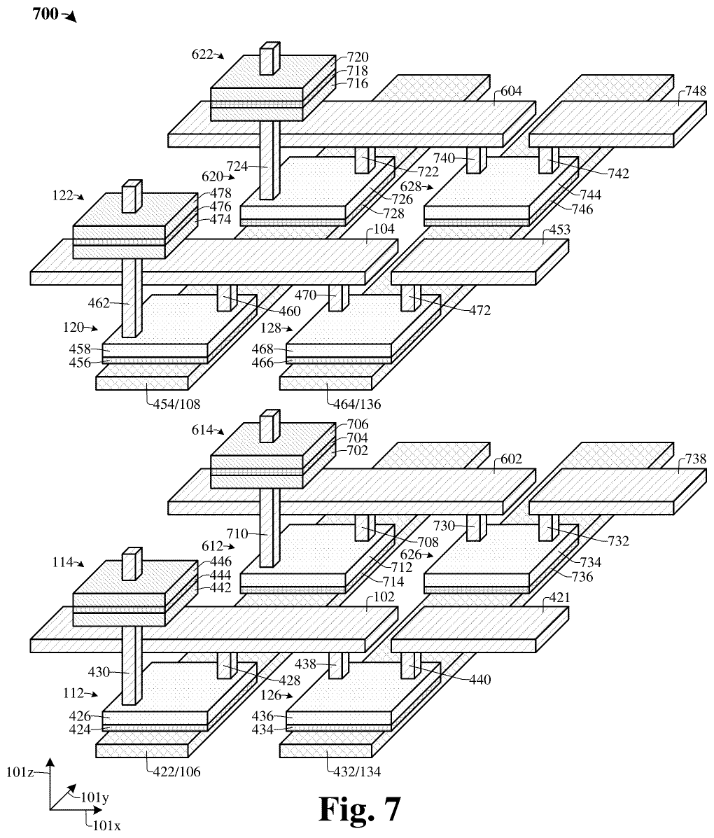

FIG. 7 illustrates a three-dimensional view 700 of some embodiments of three-dimensional DRAM device of FIG. 6.

The third memory cell capacitor 614 includes: a first electrode layer 702; a second electrode layer 706; and an insulator layer 704 between the first electrode layer 702 and the second electrode layer 706. Further, the third memory cell transistor 612 includes: a first source/drain electrode 708; a second source/drain electrode 710; a channel layer 712; a gate electrode (e.g., the first word line 106); and a gate dielectric layer 714. The first source/drain electrode 708 extends from the channel layer 712 to the third bit line 602. The second source/drain electrode 710 extends from the channel layer 712 to the first electrode layer 702 of the third memory cell capacitor 614.

Similarly, the fourth memory cell capacitor 622 includes: a first electrode layer 716; a second electrode layer 720; and an insulator layer 718 between the first electrode layer 716 and the second electrode layer 720. Further, the fourth memory cell transistor 620 includes: a first source/drain electrode 722; a second source/drain electrode 724; a channel layer 726; a gate electrode (e.g., the second word line 108); and a gate dielectric layer 728. The first source/drain electrode 722 extends from the channel layer 726 to the fourth bit line 604. The second source/drain electrode 724 extends from the channel layer 726 to the first electrode layer 716 of the fourth memory cell capacitor 622.

The third bit line transistor 626 includes: a first source/drain electrode 730; a second source/drain electrode 732; a channel layer 734; a gate electrode (e.g., the first switch line 134); and a gate dielectric layer 736. The first source/drain electrode 730 extends from the channel layer 734 to the third bit line 602. The second source/drain electrode 732 extends from the channel layer 734 to a conductive line 738 (which is coupled to the second sense amplifier 624 by conductive interconnects).

The fourth bit line transistor 628 includes: a first source/drain electrode 740; a second source/drain electrode 742; a channel layer 744; a gate electrode (e.g., the second switch line 136); and a gate dielectric layer 746. The first source/drain electrode 740 extends from the channel layer 744 to the fourth bit line 604. The second source/drain electrode 742 extends from the channel layer 744 to a conductive line 748 (which is coupled to the second sense amplifier 624 by conductive interconnects).

The word lines 106, 108 and switch lines 134, 136 are elongated in a first direction (e.g., along axis 101y). The bit lines 102, 104, 602, 604 are elongated along a second direction (e.g., along axis 101x) transverse to the first direction.

The second bit line 104 is vertically spaced over the first bit line 102 (e.g., along axis 101z). The fourth bit line 604 is vertically spaced over the third bit line 602. The third bit line 602 is laterally spaced from the first bit line 102 in the first direction (e.g., along axis 101y). The fourth bit line 604 is laterally spaced from the second bit line 104 in the first direction.

The second word line 108 is vertically spaced over the first word line 106 (e.g., along axis 101z). The second switch line 136 is vertically spaced over the first switch line 134. The first switch line 134 is laterally spaced from the first word line 106 in the second direction (e.g., along axis 101x). The second switch line 136 is laterally spaced from the second word line 108 in the second direction.

The second memory cell transistor 120 is vertically spaced over the first memory cell transistor 112 (e.g., along axis 101z). The fourth memory cell transistor 620 is vertically spaced over the third memory cell transistor 612. The third memory cell transistor 612 is laterally spaced from the first memory cell transistor 112 in the first direction (e.g., along axis 101y). The fourth memory cell transistor 620 is laterally spaced from the second memory cell transistor 120 in the first direction.

The second memory cell capacitor 122 is vertically spaced over the first memory cell capacitor 114 (e.g., along axis 101z). The fourth memory cell capacitor 622 is vertically spaced over the third memory cell capacitor 614. The third memory cell capacitor 614 is laterally spaced from the first memory cell capacitor 114 in the first direction (e.g., along axis 101y). The fourth memory cell capacitor 622 is laterally spaced from the second memory cell capacitor 122 in the first direction.

The second bit line transistor 128 is vertically spaced over the first bit line transistor 126 (e.g., along axis 101z). The fourth bit line transistor 628 is vertically spaced over the third bit line transistor 626. The third bit line transistor 626 is laterally spaced from the first bit line transistor 126 in the first direction (e.g., along axis 101y). The fourth bit line transistor 628 is laterally spaced from the second bit line transistor 128 in the first direction.

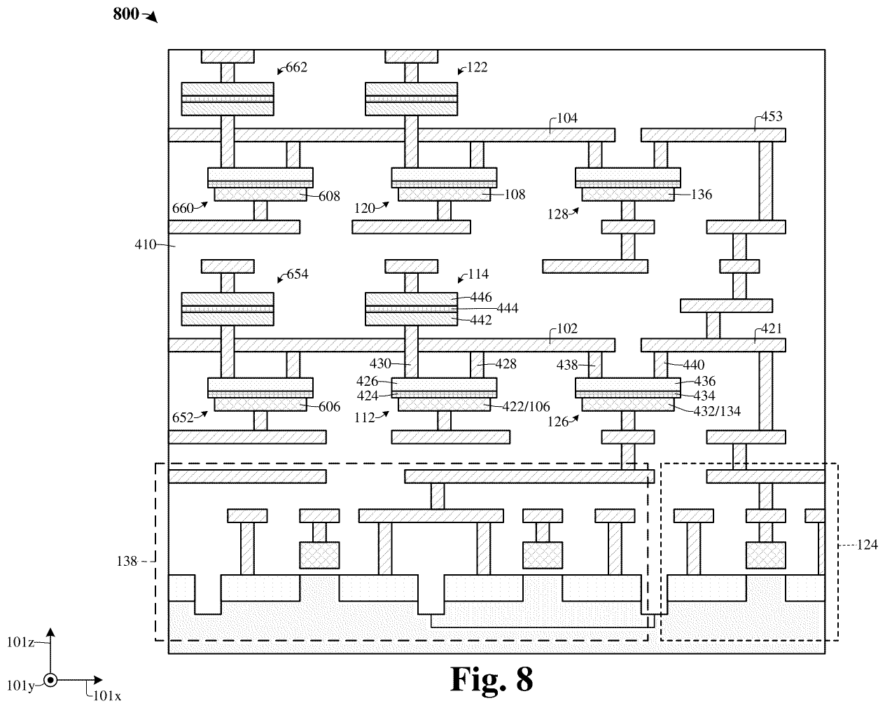

FIGS. 8-12 illustrate cross-sectional views 800-1200 of various embodiments of the integrated chip of FIG. 4.

In some embodiments (e.g., as illustrated in FIG. 8), the memory cell capacitors are planar metal-insulator-metal (MIM) capacitors. For example, the second electrode layer 446, the insulator layer 444, and the first electrode layer 442 of the first memory cell capacitor 114 are each substantially planar. The second electrode layer 446 is over the insulator layer 444, and the insulator layer 444 is over the first electrode layer 442.

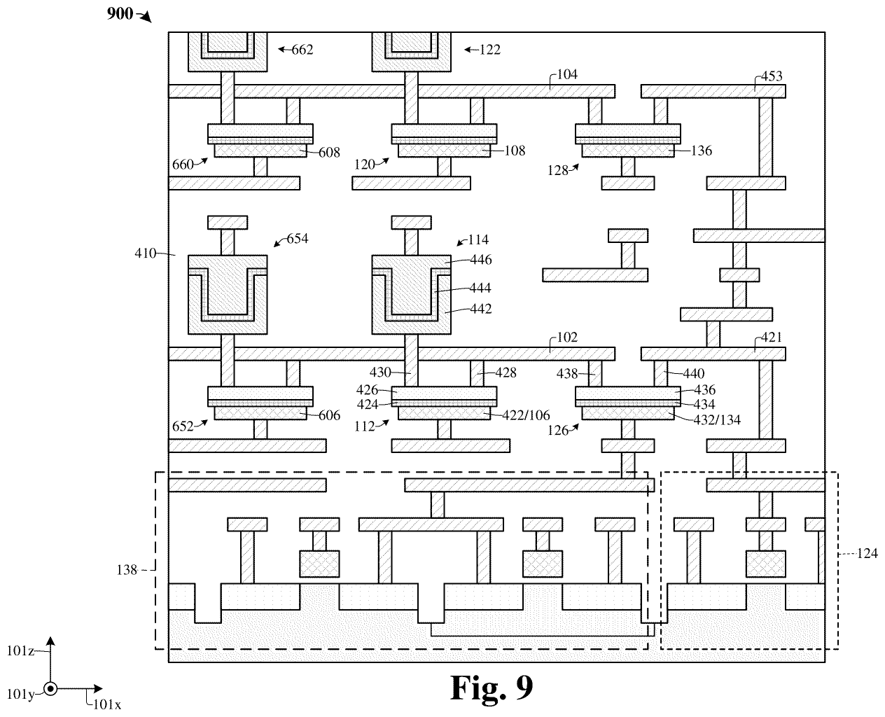

In some embodiments (e.g., as illustrated in FIG. 9), the memory cell capacitors are cylinder-type capacitors or trench capacitors. For example, the first electrode layer 442 of the first memory cell capacitor 114 has a lower portion and a side portion that extends upward from the lower portion. The insulator layer 444 lines upper surfaces and sidewalls of the first electrode layer 442. The second electrode layer 446 lines sidewalls and upper surfaces of the insulator layer 444. The first electrode layer 442 laterally surrounds the insulator layer 444, and the insulator layer 444 laterally surrounds the second electrode layer 446.

In some embodiments (e.g., as illustrated in FIG. 10), the memory cell capacitors are pillar-type capacitors. For example, the first electrode layer 442 of the first memory cell capacitor 114 has a lower portion and pillar portions that extends upward from the lower portion. The second electrode layer 446 has an upper portion and pillar portions that extend downward from the upper portion. The pillar portions of the first electrode layer 442 and the pillar portions of the second electrode layer 446 are interdigitated. The insulator layer 444 extends between the first electrode layer 442 and the second electrode layer 446.

In some embodiments (e.g., as illustrated in FIG. 8), the memory cell transistors and the bit line transistors are bottom-gate transistors. For example, the gate dielectric layer 424 of the first memory cell transistor 112 is over the gate electrode 422 (e.g., the first word line 106) of the first memory cell transistor 112. The channel layer 426 is over the gate dielectric layer 424. The source/drain electrodes 428, 430 are over the channel layer 426. Similarly, the gate dielectric layer 434 of the first bit line transistor 126 is over the gate electrode 432 (e.g., the first switch line 134) of the first bit line transistor 126. The channel layer 436 is over the gate dielectric layer 434. The source/drain electrodes 438, 440 are over the channel layer 436. In some such embodiments, the bit lines are over their corresponding memory cell transistors and bit line transistors.

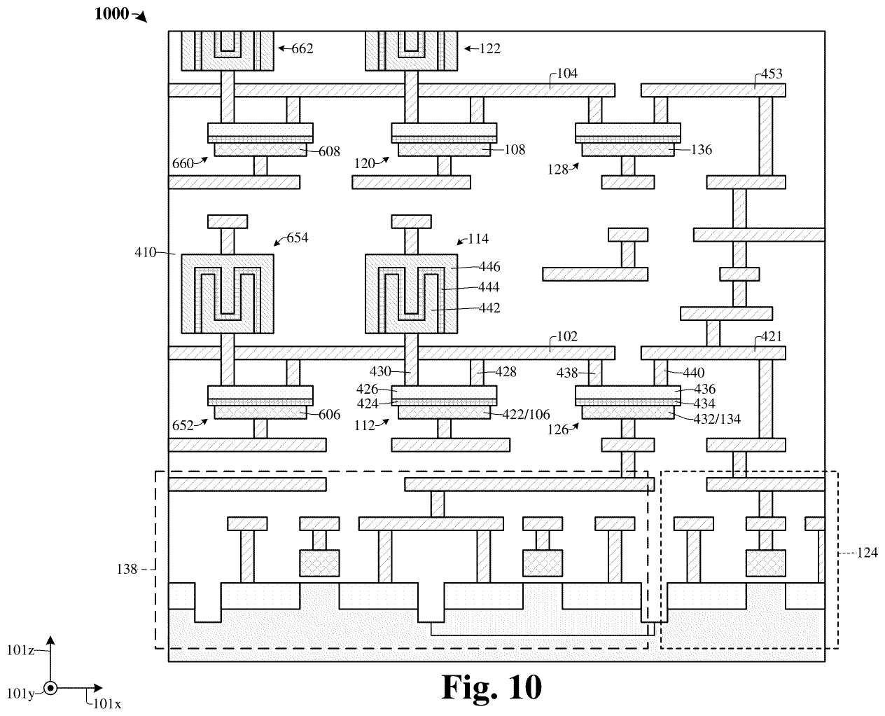

In some embodiments (e.g., as illustrated in FIG. 11), the memory cell transistors and the bit line transistors are top-gate transistors. For example, the gate dielectric layer 424 of the first memory cell transistor 112 is over the channel layer 426 of the first memory cell transistor 112. The gate electrode 422 (e.g., the first word line 106) is over the gate dielectric layer 424. The source/drain electrodes 428, 430 are over the channel layer 426 and on opposite sides of the gate electrode 422. Similarly, the gate dielectric layer 434 of the first bit line transistor 126 is over the channel layer 436 of the first bit line transistor 126. The gate electrode 432 (e.g., the first switch line 134) is over the gate dielectric layer 434. The source/drain electrodes 438, 440 are over the channel layer 436 and on opposite sides of the gate electrode 432.

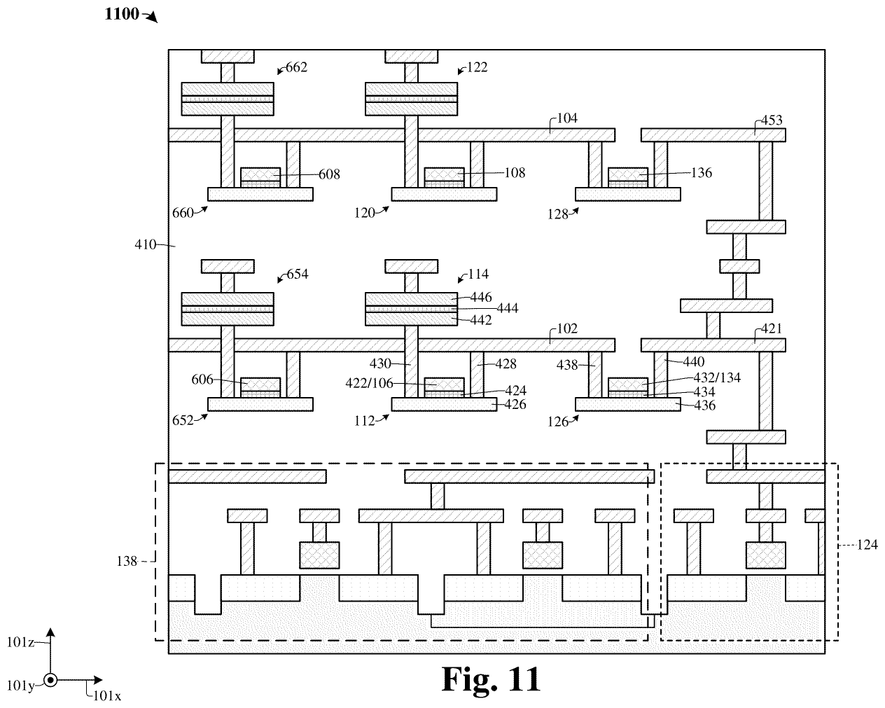

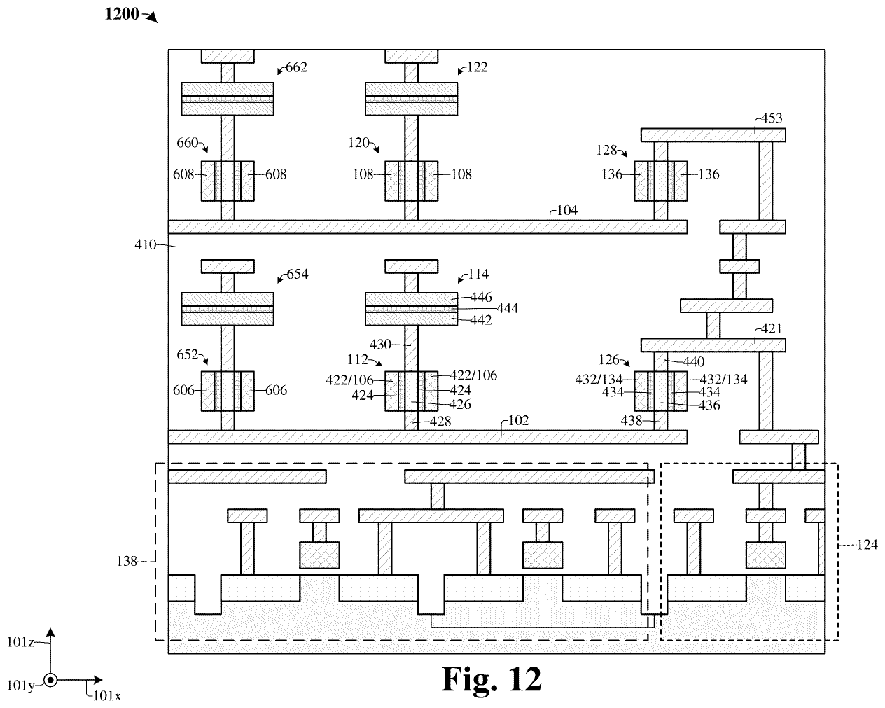

In some embodiments (e.g., as illustrated in FIG. 12), the memory cell transistors and the bit line transistors are vertical-channel transistors (e.g., gate all-around transistors or the like). For example, the gate dielectric layer 424 of the first memory cell transistor 112 laterally surrounds the channel layer 426 of the first memory cell transistor 112. The gate electrode 422 (e.g., the first word line 106) laterally surrounds the gate dielectric layer 424. The first source/drain electrode 428 is under the channel layer 426, and the second source/drain electrode 430 is over the channel layer 426. Similarly, the gate dielectric layer 434 of the first bit line transistor 126 laterally surrounds the channel layer 436 of the first bit line transistor 126. The gate electrode 432 (e.g., the first switch line 134) laterally surrounds the gate dielectric layer 434. The first source/drain electrode 438 is under the channel layer 436, and the second source/drain electrode 440 is over the channel layer 436. In some such embodiments, the bit lines are under their corresponding memory cell transistors and bit line transistors.

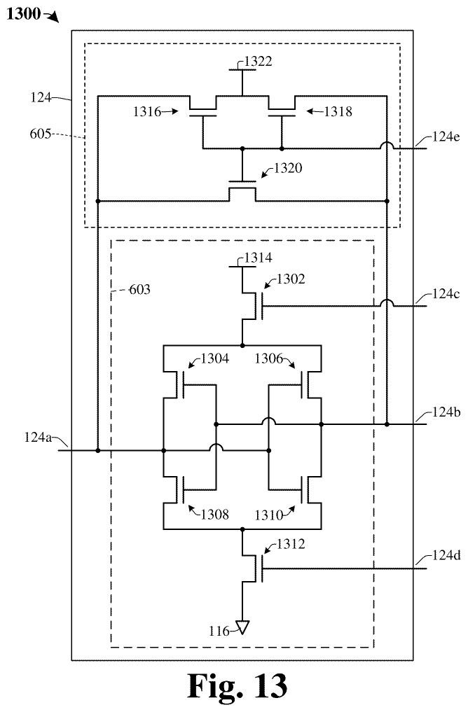

FIG. 13 illustrates a circuit diagram 1300 of some embodiments of the first sense amplifier 124.

The first sense amplifier 124 comprises the sensing circuit 603 and the equalization and pre-charge circuit 605. The sensing circuit 603 comprises a first transistor 1302, a second transistor 1304, a third transistor 1306, a fourth transistor 1308, a fifth transistor 1310, and a sixth transistor 1312 coupled as shown. A terminal (not labeled) of the first transistor 1302 is coupled to a first supply voltage terminal 1314 (e.g., VDD). A control terminal (not labeled) of the first transistor 1302 is coupled to an input terminal 124c of the first sense amplifier 124. A control terminal of the sixth transistor 1312 is coupled to an input terminal 124d of the first sense amplifier 124.

The equalization and pre-charge circuit 605 comprises a first transistor 1316, a second transistor 1318, and a third transistor 1320 coupled as shown. A terminal of transistor 1316 and a terminal of transistor 1318 are coupled to a second supply voltage terminal 1322 (e.g., VDD/2). In some embodiments, the voltage supplied to the second voltage supply terminal 1322 is half of the voltage supplied to the first supply voltage terminal 1314. A control terminal of transistor 1316, a control terminal of transistor 1318, and a control terminal of transistor 1320 are coupled to an input terminal 124e of the first sense amplifier 124.

In some embodiments, transistors 1302, 1304, 1306 are a first type (e.g., N-channel metal-oxide-semiconductor field-effect transistors (MOSFETs) or the like), and transistors 1308, 1310, 1312 are a second type (e.g., P-channel MOSFETs or the like). In some embodiments, transistors 1316, 1318, 1320 are the first type.

FIGS. 14-20 illustrate cross-sectional views 1400-2000 of some embodiments of a method for forming an integrated chip including a three-dimensional DRAM device with a bit line transistor selectively coupling a bit line to a sense amplifier. Although FIGS. 14-20 are described in relation to a method, it will be appreciated that the structures disclosed in FIGS. 14-20 are not limited to such a method, but instead may stand alone as structures independent of the method.

As shown in cross-sectional view 1400 of FIG. 14, sense amplifiers (e.g., sense amplifier 124) and word line driver circuits (e.g., word line driver circuit 138) are formed along a semiconductor substrate 402. For example, transistors 404 are formed along the semiconductor substrate 402. Further, conductive interconnects (e.g., interconnects 412, 414) are formed over the semiconductor substrate 402 and within dielectric layers 410-1, 410-2 of dielectric structure 410.

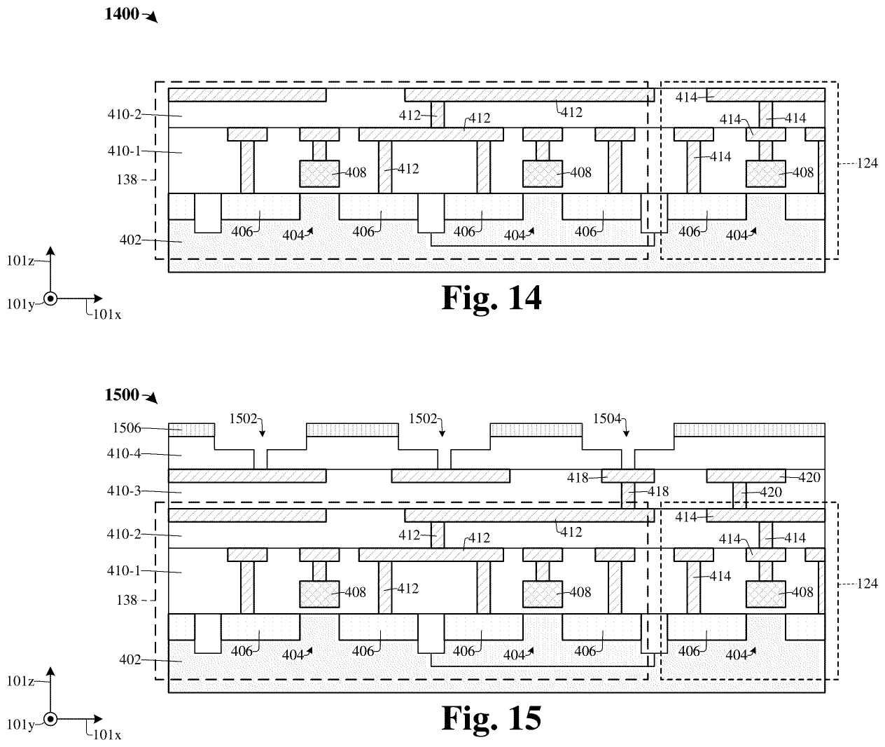

As shown in cross-sectional view 1500 of FIG. 15, dielectric layers 410-3, 410-4 of the dielectric structure 410 are formed over the semiconductor substrate 402. Conductive interconnects (e.g., interconnects 418, 420) are formed within dielectric layer 410-3. Dielectric layer 410-4 is etched to form word line openings 1502 and a switch line opening 1504. In some embodiments, a masking layer 1506 is formed over dielectric layer 410-4 and the etching is performed according to the masking layer 1506. In some embodiments, the etching comprises a dry etching process such as, for example, a plasma etching process, a reactive ion etching process, an ion beam etching process, or some other suitable process. In some embodiments, the masking layer 1506 comprises photoresist, a hard mask material, or some other suitable material.

In some embodiments, the switch line opening 1504 is approximately identical to the word line openings 1502. Thus, no additional process steps and no additional masks are needed to form the switch line opening 1504. As a result, forming the switch line opening 1504 may not substantially increase the cost of forming the integrated chip.

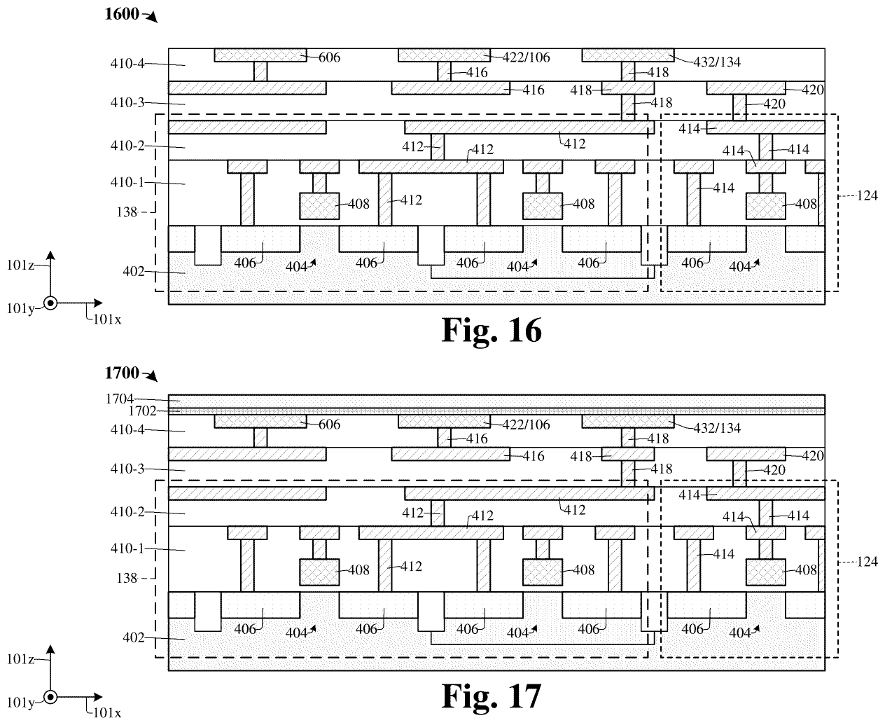

As shown in cross-sectional view 1600 of FIG. 16, word lines (e.g., word lines 106, 606) are formed in the word line openings 1502 and a switch line (e.g., switch line 134) is formed in the switch line opening 1504. For example, a conductive material (e.g., copper, tungsten, aluminum, or some other suitable material) is deposited in the openings by a chemical vapor deposition (CVD) process, a physical vapor deposition (PVD) process, an atomic layer deposition (ALD) process, or some other suitable process. Further, a planarization process (e.g., a chemical mechanical planarization process, a planarizing etch process, or some other suitable process) is performed on the conductive material to further delimit the word lines and switch line.

In some embodiments, the switch line is formed of the same material as the word lines. Thus, no additional process steps and no additional materials are needed to form the switch line. As a result, forming the switch line may not substantially increase the cost of forming the integrated chip.

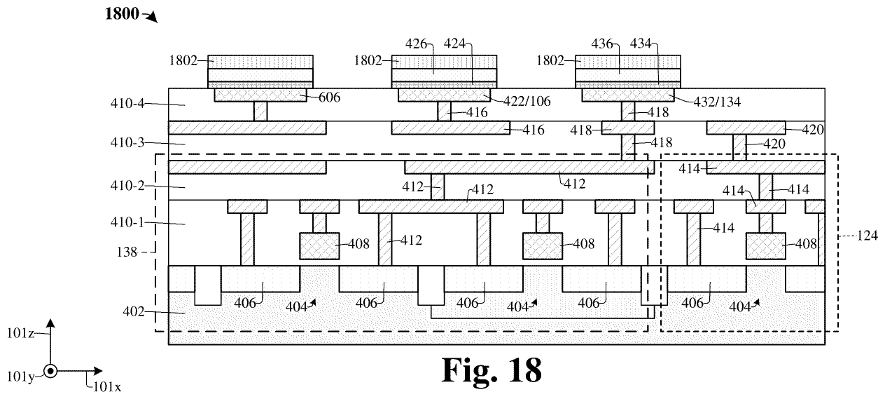

As shown in cross-sectional view 1700 of FIG. 17, a gate dielectric material layer 1702 is deposited over the word lines (e.g., word lines 106, 606) and the switch line (e.g., switch line 134) and over dielectric layer 410-4. Further, a channel material layer 1704 is deposited over the gate dielectric material layer 1702. In some embodiments, the gate dielectric material layer 1702 comprises silicon oxide, hafnium oxide, or some other suitable material and is deposited by a CVD process, a PVD process, and ALD process, or some other suitable process. In some embodiments, the channel material layer 1704 comprises silicon or some other suitable semiconductor material and is deposited by an epitaxial growth process, a CVD process, a PVD process, and ALD process, or some other suitable process.

As shown in cross-sectional view 1800 of FIG. 18, the channel material layer 1704 and the gate dielectric material layer 1702 are etched to form individual channel layers (e.g., channel layers 426, 436) and individual gate dielectric layers (e.g., gate dielectric layers 424, 434). In some embodiments, a masking layer 1802 is formed over channel material layer 1704 and the etching is performed according to the masking layer 1802. In some embodiments, the etching comprises a dry etching process or some other suitable process. In some embodiments, the masking layer 1802 comprises photoresist, a hard mask material, or some other suitable material.

In some embodiments, the sizes and shapes of the channel layers and gate dielectric layers of the switch line transistor are approximately identical those of the memory cell transistors. Thus, no additional process steps and no additional masks are needed to form the channel layers and gate dielectric layers of the switch line transistor. Further, because the channel layers and gate dielectric layers of the switch line transistor are formed of the same materials as the channel layers and gate dielectric layers of the memory cell transistors, no additional process steps and no additional materials are needed to form the switch line transistor. As a result, forming the channel layers and gate dielectric layers of the switch line transistor may not substantially increase the cost of forming the integrated chip.

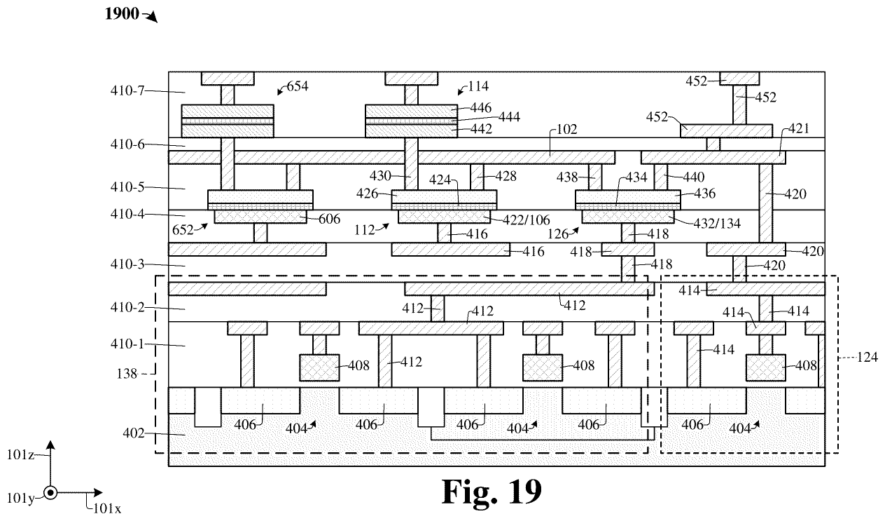

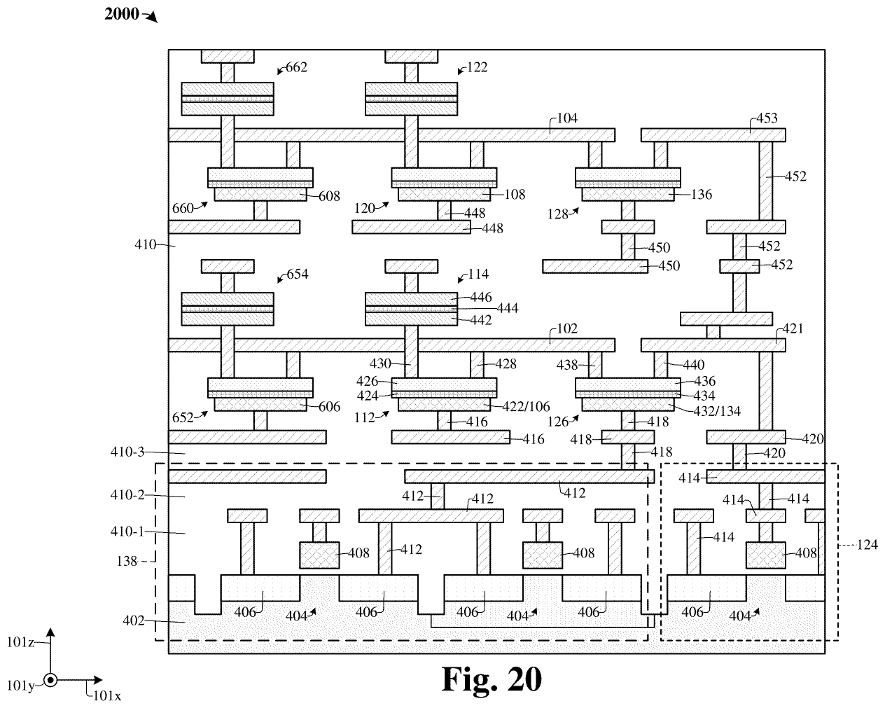

As shown in cross-sectional view 1900 of FIG. 19, dielectric layers 410-5, 410-6, 410-7 of dielectric structure 410 are formed over the channel layers, source/drain electrodes (e.g., source/drain electrodes 428, 430, 438, 440) are formed over the channel layers, bit lines (e.g., bit line 102) are formed over source/drain electrodes, and memory cell capacitors (e.g., memory cell capacitors 114, 654) are formed over the memory cell transistors (e.g., memory cell transistors 112, 652). For example, source/drain electrode 428 is formed on channel layer 426 and source/drain electrode 438 is formed on channel layer 436. Further, the bit line 102 is formed on source/drain electrodes 428, 438. In addition, source/drain electrode 430 is formed on channel layer 426 and memory cell capacitor 114 is formed on source/drain electrode 430.

As shown in cross-sectional view 2000 of FIG. 20, additional word lines (e.g., word lines 108, 608), bit lines (e.g., bit line 104), memory cell transistors (e.g., memory cell transistors 120, 660), memory cell capacitors (e.g., memory cell capacitors 122, 662), switch lines (e.g., switch line 136), bit line transistor (e.g., bit line transistor 128), etc. are formed over the semiconductor substrate 402 and within dielectric structure 410.

Thus, the present disclosure relates to a three-dimensional dynamic random access memory (DRAM) device including a bit line transistor selectively coupling a bit line to a sense amplifier.

Accordingly, in some embodiments, the present disclosure relates to a circuit including a first bit line, a second bit line, a first word line, a second word line, a first memory cell, a second memory cell, a first sense amplifier, a first bit line transistor, and a second bit line transistor. The first memory cell is coupled to the first bit line and the first word line. The second memory cell is coupled to the second bit line and the second word line. The first sense amplifier has a first terminal. The first bit line transistor selectively couples the first bit line to the first terminal of the first sense amplifier. The second bit line transistor selectively couples the second bit line to the first terminal of the first sense amplifier.

In other embodiments, the present disclosure relates to an integrated chip including a semiconductor substrate, a first sense amplifier, a first bit line, a second bit line, a first word line, a second word line, a first memory cell, a second memory cell, a first bit line transistor, and a second bit line transistor. The first sense amplifier is disposed along the semiconductor substrate. A first conductive interconnect is coupled to first sense amplifier. The first bit line is spaced over the semiconductor substrate. The second bit line is spaced over the first bit line. The first word line is spaced over the semiconductor substrate. The second word line is spaced over the first word line. The first memory cell is spaced over the semiconductor substrate and coupled to the first bit line and the first word line. The second memory cell is spaced over the first memory cell and coupled to the second bit line and the second word line. The first bit line transistor is spaced over the semiconductor substrate and laterally spaced from the first memory cell. The first bit line transistor includes a first source/drain electrode coupled to the first bit line and a second source/drain electrode coupled to the first conductive interconnect. The second bit line transistor is spaced over the first bit line transistor and laterally spaced from the second memory cel. The second bit line transistor includes a first source/drain electrode coupled to the second bit line and a second source/drain electrode coupled to the first conductive interconnect.

In yet other embodiments, the present disclosure relates to a method including providing a first switch line voltage to a control terminal of a first bit line transistor to cause the first bit line transistor to couple a first bit line to a first terminal of a first sense amplifier. A first memory cell is coupled to the first bit line and a first word line. The method includes providing a second switch line voltage to a control terminal of a second bit line transistor to cause the second bit line transistor to isolate a second bit line from the first terminal of the first sense amplifier. A second memory cell is coupled to the second bit line and a second word line. The method includes providing a pre-charge voltage to the first bit line in response to providing the first switch line voltage to the control terminal of the first bit line transistor and providing the second switch line voltage to the control terminal of the second bit line transistor. The method includes providing a first word line voltage to the first word line to assert the first word line in response to providing the pre-charge voltage to the first bit line. The method includes determining a change from the pre-charge voltage on the first bit line in response to asserting the first word line. The method includes determining a value stored in the first memory cell based on the change from the pre-charge voltage on the first bit line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit comprising:
a first bit line and a second bit line;
a first word line and a second word line;
a first memory cell coupled to the first bit line and the first word line;
a second memory cell coupled to the second bit line and the second word line;
a first sense amplifier having a first terminal;
a first bit line transistor selectively coupling the first bit line to the first terminal of the first sense amplifier; and
a second bit line transistor selectively coupling the second bit line to the first terminal of the first sense amplifier.

2. The circuit of claim 1, further comprising:
a third bit line and a fourth bit line;
a third memory cell coupled to the third bit line and the first word line;
a fourth memory cell coupled to the fourth bit line and the second word line;
a second sense amplifier having a first terminal;
a third bit line transistor selectively coupling the third bit line to the first terminal of the second sense amplifier; and
a fourth bit line transistor selectively coupling the fourth bit line to the first terminal of the second sense amplifier.

3. The circuit of claim 2, further comprising:
a first switch line coupled to a control terminal of the first bit line transistor and a control terminal of the third bit line transistor; and
a second switch line coupled to a control terminal of the second bit line transistor and a control terminal of the fourth bit line transistor.

4. The circuit of claim 3, further comprising:
a first word line driver circuit having a first output terminal coupled to the first word line and a second output terminal coupled to the first switch line; and
a second word line driver circuit having a first output terminal coupled to the second word line and a second output terminal coupled to the second switch line.

5. The circuit of claim 3, wherein a first terminal of the first bit line transistor is coupled to the first bit line and a second terminal of the first bit line transistor is coupled to the first terminal of the first sense amplifier,
wherein a first terminal of the second bit line transistor is coupled to the second bit line and a second terminal of the second bit line transistor is coupled to the first terminal of the first sense amplifier,
wherein a first terminal of the third bit line transistor is coupled to the third bit line and a second terminal of the third bit line transistor is coupled to the first terminal of the second sense amplifier, and
wherein a first terminal of the fourth bit line transistor is coupled to the fourth bit line and a second terminal of the fourth bit line transistor is coupled to the first terminal of the second sense amplifier.

6. The circuit of claim 1, further comprising:
a first complementary bit line and a second complementary bit line;
a third word line and a fourth word line;
a third memory cell coupled to the first complementary bit line and the third word line;
a fourth memory cell coupled to the second complementary bit line and the fourth word line;
a third bit line transistor selectively coupling the first complementary bit line to a second terminal of the first sense amplifier; and
a fourth bit line transistor selectively coupling the second complementary bit line to the second terminal of the first sense amplifier.

7. The circuit of claim 1, wherein the first memory cell comprises a first memory cell transistor and a first memory cell capacitor, wherein the first memory cell transistor has a first terminal coupled to the first bit line, a second terminal coupled to a first terminal of the first memory cell capacitor, and a control terminal coupled to the first word line, and
wherein the first bit line transistor has a first terminal coupled the first bit line, a second terminal coupled to the first terminal of the first sense amplifier, and a control terminal coupled to a first switch line.

8. The circuit of claim 1, further comprising:
a third word line and a fourth word line;
a third memory cell coupled to the first bit line and the third word line; and
a fourth memory cell coupled to the second bit line and the fourth word line.

9. An integrated chip comprising:
a semiconductor substrate;
a first sense amplifier disposed along the semiconductor substrate, wherein a first conductive interconnect is coupled to first sense amplifier;
a first bit line spaced over the semiconductor substrate;
a second bit line spaced over the first bit line;
a first word line spaced over the semiconductor substrate;
a second word line spaced over the first word line;
a first memory cell spaced over the semiconductor substrate and coupled to the first bit line and the first word line;
a second memory cell spaced over the first memory cell and coupled to the second bit line and the second word line;
a first bit line transistor spaced over the semiconductor substrate and laterally spaced from the first memory cell, the first bit line transistor comprising a first source/drain electrode coupled to the first bit line and a second source/drain electrode coupled to the first conductive interconnect; and
a second bit line transistor spaced over the first bit line transistor and laterally spaced from the second memory cell, the second bit line transistor comprising a first source/drain electrode coupled to the second bit line and a second source/drain electrode coupled to the first conductive interconnect.

10. The integrated chip of claim 9, further comprising:
a second sense amplifier disposed along the semiconductor substrate, wherein a second conductive interconnect is coupled to the second sense amplifier;
a third bit line spaced over the semiconductor substrate and laterally spaced from the first bit line;
a fourth bit line spaced over the third bit line;
a third memory cell spaced over the semiconductor substrate and laterally spaced from the first memory cell, the third memory cell coupled to the third bit line and the first word line;
a fourth memory cell spaced over the third memory cell and coupled to the fourth bit line and the second word line;
a third bit line transistor spaced over the semiconductor substrate and laterally spaced from the third memory cell and the first bit line transistor, the third bit line transistor comprising a first source/drain electrode coupled to the third bit line and a second source/drain electrode coupled to the second conductive interconnect; and
a fourth bit line transistor spaced over the third bit line transistor and laterally spaced from the fourth memory cell and the second bit line transistor, the fourth bit line transistor comprising a first source/drain electrode coupled to the fourth bit line and a second source/drain electrode coupled to the second conductive interconnect.

11. The integrated chip of claim 10, further comprising:
a first switch line forming a gate electrode of the first bit line transistor and a gate electrode of the third bit line transistor, the first switch line spaced over the semiconductor substrate and laterally spaced from the first word line; and
a second switch line forming a gate electrode of the second bit line transistor and a gate electrode of the fourth bit line transistor, the first switch line spaced over the first switch line and laterally spaced from the second word line.

12. The integrated chip of claim 11, wherein the first word line and the second word line are elongated in a first direction, the first bit line and the second bit line are elongated in a second direction, transverse to the first direction, and the first switch line and the second switch line are elongated in the first direction.

13. The integrated chip of claim 11, further comprising:
a first word line driver circuit disposed along the semiconductor substrate, the first word line driver circuit coupled to the first word line by a first plurality of conductive interconnects over the semiconductor substrate, the first word line driver circuit coupled to the first switch line by a second plurality of conductive interconnects over the semiconductor substrate; and
a second word line driver circuit disposed along the semiconductor substrate, the second word line driver circuit coupled to the second word line by a third plurality of conductive interconnects over the semiconductor substrate, the second word line driver circuit coupled to the first switch line by a fourth plurality of conductive interconnects over the semiconductor substrate.

14. The integrated chip of claim 9, wherein the first memory cell comprises a first memory cell transistor and a first memory cell capacitor,
wherein the first memory cell capacitor comprises a first electrode layer, a second electrode layer, and an insulator layer between the first electrode layer and the second electrode layer,
wherein the first memory cell transistor comprises a first gate electrode coupled to the first word line, a first channel layer spaced from the first gate electrode, a first source/drain electrode extending from the first channel layer to the first bit line, a second source/drain electrode extending from the first channel layer to a first electrode layer of the first memory cell capacitor, and
wherein the first bit line transistor further comprises a second gate electrode coupled to a first switch line and a second channel layer spaced from the second gate electrode, wherein the first source/drain electrode of the first bit line transistor extends from the second channel layer to the first bit line, and wherein the second source/drain electrode of the first bit line transistor extends from the second channel layer to the first conductive interconnect.

15. The integrated chip of claim 14, wherein the first word line forms the first gate electrode, and wherein the first switch line forms the second gate electrode.

16. The integrated chip of claim 9, wherein a plurality of conductive interconnects extend from the first conductive interconnect to a first terminal of the first sense amplifier and couple the first conductive interconnect to the first terminal of the first sense amplifier.

17. A method comprising:
providing a first switch line voltage to a control terminal of a first bit line transistor to cause the first bit line transistor to couple a first bit line to a first terminal of a first sense amplifier, wherein a first memory cell is coupled to the first bit line and a first word line;
providing a second switch line voltage to a control terminal of a second bit line transistor to cause the second bit line transistor to isolate a second bit line from the first terminal of the first sense amplifier, wherein a second memory cell is coupled to the second bit line and a second word line;
providing a pre-charge voltage to the first bit line in response to providing the first switch line voltage to the control terminal of the first bit line transistor and providing the second switch line voltage to the control terminal of the second bit line transistor;
providing a first word line voltage to the first word line to assert the first word line in response to providing the pre-charge voltage to the first bit line;
determining a change from the pre-charge voltage on the first bit line in response to asserting the first word line; and
determining a value stored in the first memory cell based on the change from the pre-charge voltage on the first bit line.

18. The method of claim 17, further comprising:
providing a write voltage to the first bit line to write the first memory cell in response to determining the value stored in the first memory cell;
providing a second word line voltage to the first word line to de-assert the first word line in response to writing the first memory cell;
providing the pre-charge voltage to bit line in response to de-asserting the first word line; and
providing the second switch line voltage to the control terminal of the first bit line transistor to cause the first bit line transistor to isolate the first bit line from the first terminal of the first sense amplifier in response to providing the pre-charge voltage to the first bit line in response to de-asserting the first word line.

19. The method of claim 17, further comprising;
providing the first switch line voltage to a control terminal of a third bit line transistor to cause the third bit line transistor to couple a third bit line to a first terminal of a second sense amplifier, wherein a third memory cell is coupled to the third bit line and the first word line;
providing the second switch line voltage to a control terminal of a fourth bit line transistor to cause the fourth bit line transistor to isolate a fourth bit line from the first terminal of the second sense amplifier, wherein a fourth memory cell is coupled to the fourth bit line and the second word line; and
providing the pre-charge voltage to the third bit line in response to providing the first switch line voltage to the control terminal of the third bit line transistor and providing the second switch line voltage to the control terminal of the fourth bit line transistor.

20. The method of claim 17, further comprising:
providing the first switch line voltage to a control terminal of a first complementary bit line transistor to cause the first complementary bit line transistor to couple a first complementary bit line to a second terminal of the first sense amplifier;
providing the second switch line voltage to a control terminal of a second complementary bit line transistor to cause the second complementary bit line transistor to isolate a second complementary bit line from the second terminal of the first sense amplifier; and
providing the pre-charge voltage to the first complementary bit line in response to providing the first switch line voltage to the control terminal of the first complementary bit line transistor and providing the second switch line voltage to the control terminal of the second complementary bit line transistor,
wherein the change from the pre-charge voltage on the first bit line is determined by comparing the voltage on the first bit line to the pre-charge voltage on the first complementary bit line in response to asserting the first word line.
